(19) United States
(12) Patent Application Publication
(10) Pub. No.: US 2014/0299874 A1
(43) Pub. Date: Oct. 9, 2014

(54) Semiconductor Device

(71) Applicant: Semiconductor Energy Laboratory Co., Ltd., Kanagawa-ken (JP)

(72) Inventor: Shunpei Yamazaki, Tokyo (JP)

(73) Assignee: Semiconductor Energy Laboratory Co., Ltd., Kanagawa-ken (JP)

(21) Appl. No.: 14/243,257

(22) Filed: Apr. 2, 2014

(30) Foreign Application Priority Data
Apr. 3, 2013 (JP) 2013-077615

(51) Int. Cl. H01L 29/786; H01L 27/12

(52) U.S. Cl. CPC H01L 29/7869; H01L 27/1225
USPC 257/43

(57) ABSTRACT

To provide a semiconductor device including, over the same substrate, a transistor and a resistor each including an oxide semiconductor. A semiconductor device includes a resistor having a first oxide semiconductor layer covered with a nitride insulating layer containing hydrogen and a transistor having a second oxide semiconductor layer which is covered with an oxide insulating layer, has the same composition as the first oxide semiconductor layer, and has a different carrier density from the first oxide semiconductor layer. The first oxide semiconductor layer has higher carrier density than the second oxide semiconductor layer by treatment for increasing an impurity concentration. The treatment is performed on an entire surface of the first oxide semiconductor layer processed into an island shape. Therefore, in the first oxide semiconductor layer, regions contacting the nitride insulating layer and regions contacting electrode layers in contact holes of the nitride insulating layer have the same conductivity.

### BACKGROUND OF THE INVENTION

1. Field of the Invention

One embodiment of the present invention relates to a semiconductor device and a method for manufacturing the semiconductor device.

Note that a semiconductor device in this specification refers to all devices which can function by utilizing semiconductor characteristics, and electro-optical devices, semiconductor circuits, and electronic devices are all semiconductor devices.

2. Description of the Related Art

Transistors used for most flat panel displays typified by a liquid crystal display device and a light-emitting display device are formed using silicon semiconductors such as amorphous silicon, single crystal silicon, and polycrystalline silicon provided over glass substrates. Further, such a transistor employing such a silicon semiconductor is used in integrated circuits (ICs) and the like.

In recent years, attention has been drawn to a technique in which, instead of a silicon semiconductor, a metal oxide exhibiting semiconductor characteristics is used in transistors. Note that in this specification, a metal oxide exhibiting semiconductor characteristics is referred to as an oxide semiconductor.

For example, such a technique is disclosed that a transistor is manufactured using zinc oxide or an In—Ga—Zn-based oxide as an oxide semiconductor and the transistor is used as a switching element or the like in a pixel of a display device (see Patent Documents 1 and 2).

A driver circuit portion for driving a pixel portion of a display device includes elements such as a transistor, a capacitor, and a resistor.

Patent Document 3 discloses a semiconductor device in which a channel-etched transistor having an oxide semiconductor in a pixel portion and a resistor having an oxide semiconductor in a driver circuit are formed in the same process.

### REFERENCE

### Patent Documents

[Patent Document 1] Japanese Published Patent Application No. 2007-123861
[Patent Document 2] Japanese Published Patent Application No. 2007-096055
[Patent Document 3] Japanese Published Patent Application No. 2010-171394

### SUMMARY OF THE INVENTION

An object of one embodiment of the present invention is to provide a semiconductor device in which a transistor having an oxide semiconductor and a resistor having an oxide semiconductor are formed over the same substrate.

An object of another embodiment of the present invention is to provide a highly reliable semiconductor device.

Note that the descriptions of these objects do not disturb the existence of other objects. Note also that one embodiment of the present invention does not necessarily achieve all the objects listed above. Objects other than the above objects will be apparent from and can be derived from the description of the specification and the like.

One embodiment of the present invention is a semiconductor device including a resistor having a first oxide semiconductor layer and a transistor having a second oxide semiconductor layer. The first oxide semiconductor layer is covered with a nitride insulating layer containing hydrogen. The second oxide semiconductor layer is covered with an oxide insulating layer, has the same composition as that of the first oxide semiconductor layer, and has a carrier density different from that of the first oxide semiconductor layer. The carrier density of the first oxide semiconductor layer is higher than the carrier density of the second oxide semiconductor layer because the first oxide semiconductor layer is subjected to treatment for increasing an impurity concentration. The treatment is performed on an entire surface of the first oxide semiconductor layer processed into an island shape. For this reason, a region of the first oxide semiconductor layer that is in contact with the nitride insulating layer and a region of the first oxide semiconductor layer that is in contact with an electrode layer in a contact hole provided in the nitride insulating layer have the same conductivity. More specifically, any of the following structures can be employed for example.

One embodiment of the present invention is a semiconductor device including a resistor and a transistor that are provided over the same substrate. The resistor includes a first oxide semiconductor layer, a nitride insulating layer covering the first oxide semiconductor layer, and a first electrode and a second electrode that are electrically connected to the first oxide semiconductor layer in contact holes provided in the nitride insulating layer. The transistor includes a gate electrode layer, a second oxide semiconductor layer overlapping the gate electrode layer, an insulating layer between the gate electrode layer and the second oxide semiconductor layer, an oxide insulating layer covering the second oxide semiconductor layer, and a third electrode and a fourth electrode that are electrically connected to the second oxide semiconductor layer in contact holes provided in the oxide insulating layer. The first oxide semiconductor layer and the second oxide semiconductor layer have the same composition. The carrier density of the first oxide semiconductor layer is higher than the carrier density of the second oxide semiconductor layer.

Another embodiment of the present invention is a semiconductor device including a resistor and a transistor that are provided over the same substrate. The resistor includes a first nitride insulating layer, a first oxide semiconductor layer over the first nitride insulating layer, a second nitride insulating layer covering the first oxide semiconductor layer, and a first electrode and a second electrode that are electrically connected to the first oxide semiconductor layer in contact holes provided in the second nitride insulating layer. The transistor includes a gate electrode layer, the first nitride insulating layer over the gate electrode layer, a first oxide insulating layer over the first nitride insulating layer, a second oxide semiconductor layer overlapping the gate electrode layer with the first nitride insulating layer and the first oxide insulating layer provided therebetween, a second oxide insulating layer covering the second oxide semiconductor layer, the second nitride insulating layer over the second oxide insulating layer, and a third electrode and a fourth electrode that are electrically connected to the second oxide semiconductor layer in contact holes provided in the second nitride insulating layer and the second oxide insulating layer. The first oxide semiconductor layer and the second oxide semiconductor layer have the same composition. The carrier density of the first oxide semiconductor layer is higher than the carrier density of the second oxide semiconductor layer.

In the semiconductor device, the resistor may include the first oxide insulating layer between the first nitride insulating layer and the first oxide semiconductor layer.

In any of the semiconductor devices, the length of a path through which carriers flow in the resistor may be longer than the length of a path through which carriers flow in the transistor.

Any of the semiconductor devices may include a pixel portion including a plurality of pixels having the transistor and a driver circuit portion having the resistor.

One embodiment of the present invention can provide a semiconductor device in which a transistor having an oxide semiconductor and a resistor having an oxide semiconductor are formed over the same substrate.

One embodiment of the present invention can provide a highly reliable semiconductor device.

### BRIEF DESCRIPTION OF THE DRAWINGS

FIGS. 1A to 1C are plan views and a cross-sectional view illustrating one embodiment of a semiconductor device.

FIGS. 2A to 2D are cross-sectional views illustrating one embodiment of a method for manufacturing a semiconductor device.

FIGS. 3A to 3C are cross-sectional views illustrating one embodiment of a method for manufacturing a semiconductor device.

FIGS. 4A and 4B are a plan view and a cross-sectional view illustrating one embodiment of a semiconductor device.

FIGS. 5A and 5B are cross-sectional views each illustrating one embodiment of a semiconductor device.

FIGS. 6A and 6B are a cross-sectional view and a band diagram illustrating one embodiment of a semiconductor device.

FIGS. 7A to 7C are circuit diagrams illustrating one embodiment of a semiconductor device.

FIG. 8 is a cross-sectional view illustrating one embodiment of a semiconductor device.

FIGS. 9A to 9H show examples of an electronic device.

### DETAILED DESCRIPTION OF THE INVENTION

Embodiments of the present invention will be described below in detail with reference to the drawings. Note that the present invention is not limited to the description below, and it is easily understood by those skilled in the art that various changes and modifications can be made without departing from the spirit and scope of the invention. Accordingly, the present invention should not be interpreted as being limited to the content of the embodiments below. In addition, in the following embodiments, the same portions or portions having similar functions are denoted by the same reference numerals or the same hatching patterns in different drawings, and description thereof will not be repeated.

Note that in each drawing described in this specification, the size, the film thickness, or the region of each component may be exaggerated for clarity. Therefore, embodiments of the present invention are not limited to such a scale.

In this specification and the like, ordinal numbers such as “first” and “second” are used in order to avoid confusion among components, and the terms do not limit the components numerically. Therefore, for example, the term “first” can be replaced with the term “second”, “third”, or the like as appropriate.

Note that functions of a “source” and a “drain” of a transistor are sometimes replaced with each other when a transistor of opposite polarity is used or when the direction of current flowing is changed in circuit operation, for example. Therefore, the terms “source” and “drain” can be used to denote the drain and the source, respectively, in this specification.

### Embodiment 1

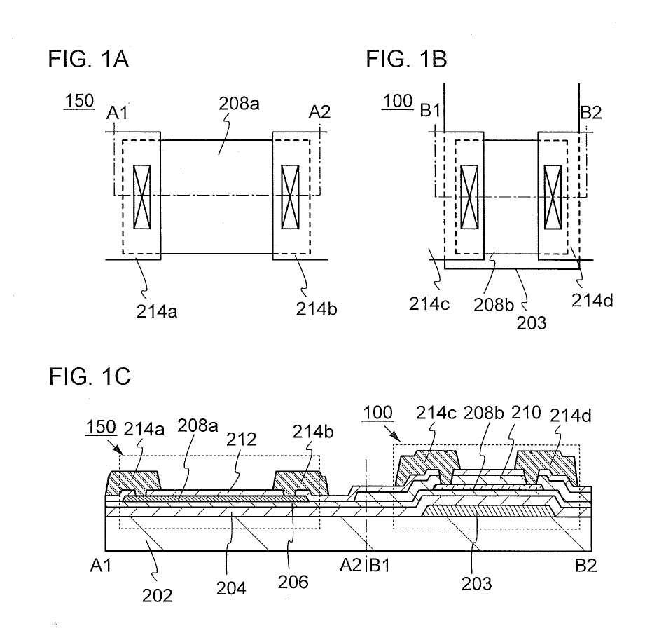

In this embodiment, a semiconductor device and a manufacturing method of the semiconductor device according to one embodiment of the present invention will be described with reference to FIGS. 1A to 1C, FIGS. 2A to 2D, FIGS. 3A to 3C, FIGS. 4A and 4B, and FIGS. 5A and 5B.

### <Example of Structure of Semiconductor Device>

FIGS. 1A to 1C illustrate an example of a structure of a semiconductor device. FIG. 1A is a plan view of a resistor 150 included in the semiconductor device. FIG. 1B is a plan view of a transistor 100 included in the semiconductor device. FIG. 1C is a cross-sectional view taken along line A1-A2 in FIG. 1A and line B1-B2 in FIG. 1B. Note that in FIGS. 1A and 1B, part of components (e.g., a nitride insulating layer 212) of the resistor 150 and the transistor 100 is omitted for simplicity. The same applies to the other plan view.

The transistor 100 shown in FIGS. 1B and 1C includes a gate electrode layer 203 provided over a substrate 202, an insulating layer 204 and an insulating layer 206 over the gate electrode layer 203, an oxide semiconductor layer 208b that is over and in contact with the insulating layer 206 and overlaps the gate electrode layer 203, an oxide insulating layer 210 covering the oxide semiconductor layer 208b, the nitride insulating layer 212 over the oxide insulating layer 210, and an electrode layer 214c and an electrode layer 214d that are electrically connected to the oxide semiconductor layer 208b in contact holes provided in the nitride insulating layer 212 and the oxide insulating layer 210.

The resistor 150 shown in FIGS. 1A and 1C includes an oxide semiconductor layer 208a over the substrate 202, the nitride insulating layer 212 covering the oxide semiconductor layer 208a, and an electrode layer 214a and an electrode layer 214b that are electrically connected to the oxide semiconductor layer 208a in contact holes provided in the nitride insulating layer 212. Note that the insulating layer 204 and the insulating layer 206 that are provided between the substrate 202 and the oxide semiconductor layer 208a may be regarded as components of the resistor 150.

The insulating layer 204, the insulating layer 206, and the nitride insulating layer 212 are shared by the transistor 100 and the resistor 150. Note that in the transistor 100, the insulating layer 204 and the insulating layer 206 serve as a gate insulating layer. In FIG. 1C, the gate insulating layer has a stacked-layer structure of the insulating layer 204 and the insulating layer 206; however, the gate insulating layer may have a single-layer structure, or a stacked-layer structure of three or more layers. The electrode layers 214a to 214d are formed in the same step. In the transistor 100, one of the electrode layer 214c and the electrode layer 214d serves as a source electrode layer, and the other serves as a drain electrode layer.

The oxide semiconductor layer 208a and the oxide semiconductor layer 208b are layers processed into island-like shapes by the same film formation step and the same etching step. An oxide semiconductor is a semiconductor material whose resistivity can be controlled by oxygen vacancies in the film of the semiconductor material and/or the concentration of impurities such as hydrogen or water in the film of the semiconductor material. Thus, the resistivity of each of the oxide semiconductor layers formed in the same step can be controlled by changing (differentiating) the structure of the insulating layer between the insulating layer in contact with the upper side (or lower side) of the oxide semiconductor layer 208a and the insulating layer in contact with the upper side (or lower side) of the oxide semiconductor layer 208b.

Specifically, when an insulating layer containing oxygen (oxide insulating layer), namely, an insulating layer capable of releasing oxygen is used as the insulating layer covering the oxide semiconductor layer 208b in which a channel of the transistor 100 is formed, oxygen can be supplied to the oxide semiconductor layer 208b. By the supply of oxygen, the oxide semiconductor layer 208b becomes a high-resistance oxide semiconductor layer in which oxygen vacancies in the layer or at the interface between the layers are filled. Note that as the insulating layer capable of releasing oxygen, a silicon oxide layer or a silicon oxynitride layer can be used, for example.

The oxide semiconductor layer 208b in which oxygen vacancies are filled and the hydrogen concentration is reduced can be referred to as a highly purified intrinsic or substantially highly purified intrinsic oxide semiconductor layer. Here, “substantially intrinsic” means the state where an oxide semiconductor has a carrier density lower than 1×10¹⁷/cm³, preferably lower than 1×10¹⁵/cm³, further preferably lower than 1×10¹³/cm³. A highly purified intrinsic or substantially highly purified intrinsic oxide semiconductor has few carrier generation sources, and thus has a low carrier density in some cases. The highly purified intrinsic or substantially highly purified intrinsic oxide semiconductor layer 208b has a low density of defect states and accordingly can have a low density of trap states.

Further, the highly purified intrinsic or substantially highly purified intrinsic oxide semiconductor layer 208b has an extremely low off-state current; even when an element has a channel width of 1×10⁶ μm and a channel length of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V. Thus, the transistor 100 whose channel region is formed in the oxide semiconductor layer 208b has a small variation in electrical characteristics and high reliability.

The oxide insulating layer 210 is formed by selectively removing a region of the oxide insulating layer 210 that overlaps the oxide semiconductor layer 208a in the resistor 150. Hence, the oxide semiconductor layer 208a is covered with the insulating layer that is different from the insulating layer covering the oxide semiconductor layer 208b. The insulating layer covering the oxide semiconductor layer 208a in the resistor 150 is an insulating layer containing hydrogen, namely, an insulating layer capable of releasing hydrogen. The insulating layer capable of releasing hydrogen is typically an inorganic insulating layer containing nitrogen, e.g., a nitride insulating layer. With the use of such an insulating layer as the insulating layer covering the oxide semiconductor layer 208a, hydrogen can be supplied to the oxide semiconductor layer 208a. The nitride insulating layer preferably has a hydrogen concentration of higher than or equal to 1×10²² atoms/cm³ in a film, in which case hydrogen can be contained in the oxide semiconductor layer 208a effectively.

Hydrogen contained in the oxide semiconductor layer 208a reacts with oxygen bonded to a metal atom to be water, and in addition, an oxygen vacancy is formed in a lattice from which oxygen is released (or a portion from which oxygen is released). Due to entry of hydrogen into the oxygen vacancy, an electron serving as a carrier is generated. Further, in some cases, bonding of part of hydrogen to oxygen bonded to a metal element causes generation of an electron serving as a carrier. Thus, the oxide semiconductor layer 208a containing hydrogen has a carrier density higher than that of the oxide semiconductor layer 208b. That is, the oxide semiconductor layer 208a that is supplied with hydrogen from the nitride insulating layer 212 is a low-resistance oxide semiconductor layer.

Hydrogen in the oxide semiconductor layer 208b where a channel is formed, of the transistor 100, is preferably reduced as much as possible. Specifically, in the oxide semiconductor layer 208b, the concentration of hydrogen which is measured by secondary ion mass spectrometry (SIMS) is set to lower than or equal to 2×10²⁰ atoms/cm³, preferably lower than or equal to 5×10¹⁹ atoms/cm³, more preferably lower than or equal to 1×10¹⁹ atoms/cm³, or lower than 5×10¹⁸ atoms/cm³, preferably lower than or equal to 1×10¹⁸ atoms/cm³, more preferably lower than or equal to 5×10¹⁷ atoms/cm³, still more preferably lower than or equal to 1×10¹⁶ atoms/cm³. On the other hand, the oxide semiconductor layer 208a included in the resistor 150 is a low-resistance oxide semiconductor layer that has high hydrogen concentration or/and a large amount of oxygen vacancies as compared to the oxide semiconductor layer 208b.

### <Method for Manufacturing Semiconductor Device>

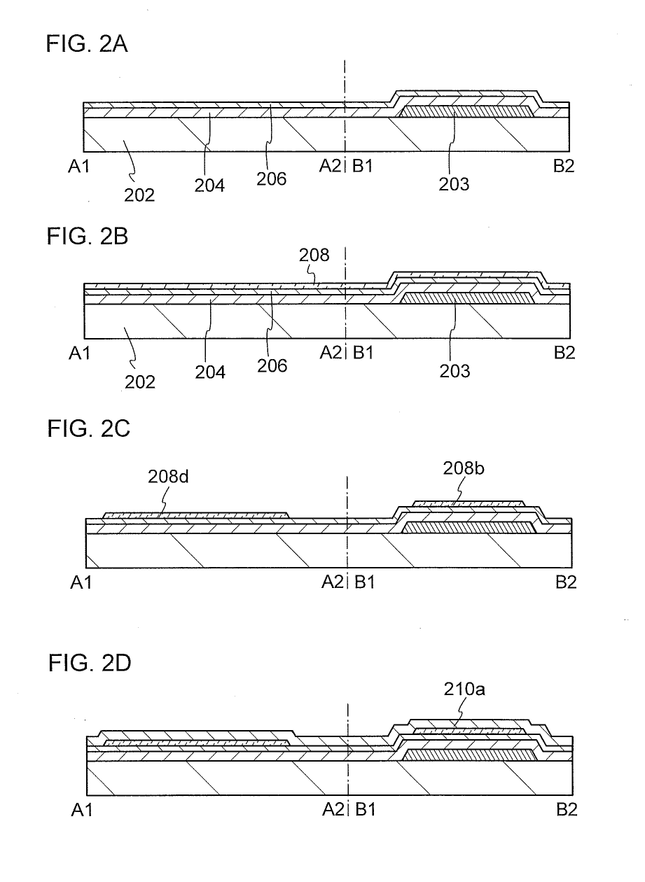

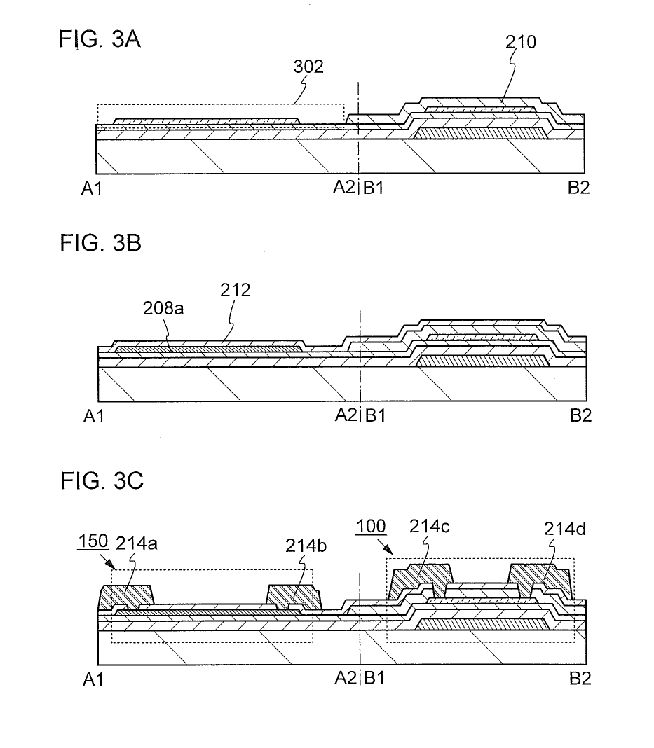

An example of a method for manufacturing a semiconductor device shown in FIGS. 1A to 1C is described with reference to FIGS. 2A to 2D and FIGS. 3A to 3C.

First, the gate electrode layer 203 (or a wiring formed in the same layer as the gate electrode layer 203) is formed over the substrate 202, and the insulating layer 204 and the insulating layer 206 are stacked over the gate electrode layer 203 (see FIG. 2A).

There is no particular limitation on the property of a material and the like of the substrate 202 as long as the material has heat resistance enough to withstand at least heat treatment to be perforated later. For example, a glass substrate, a ceramic substrate, a quartz substrate, a sapphire substrate, or the like may be used as the substrate 202. Alternatively, a single crystal semiconductor substrate or a polycrystalline semiconductor substrate made of silicon, silicon carbide, or the like, a compound semiconductor substrate made of silicon germanium or the like, an SOI (silicon on insulator) substrate, or the like may be used as the substrate 202. Furthermore, any of these substrates further provided with a semiconductor element may be used as the substrate 202. In the case where a glass substrate is used as the substrate 202, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Still further alternatively, a flexible substrate may be used as the substrate 202, and the transistor 100 and the resistor 150 may be provided directly on the flexible substrate. Further alternatively, a separation layer may be provided between the substrate 202, and the transistor 100 and the resistor 150. The separation layer can be used when part or the whole of a semiconductor device formed over the separation layer is completed and separated from the substrate 202 and transferred to another substrate. In such a case, the transistor 100 and the resistor 150 can move to a substrate having low heat resistance or a flexible substrate as well.

The gate electrode layer 203 can be formed using a metal material such as molybdenum, titanium, tantalum, tungsten, aluminum, copper, chromium, neodymium, or scandium or an alloy material that contains any of these materials as its main component. Alternatively, a semiconductor film typified by a polycrystalline silicon film doped with an impurity element such as phosphorus, or a silicide film such as a nickel silicide film may be used as the gate electrode layer 203. The gate electrode layer 203 may have either a single-layer structure or a stacked-layer structure. The gate electrode layer 203 may have a tapered shape with a taper angle of greater than or equal to 15° and less than or equal to 70° for example. Here, the taper angle refers to an angle formed between a side surface of a layer having a tapered shape and a bottom surface of the layer.

The material of the gate electrode layer 203 may be a conductive material such as indium oxide-tin oxide, indium oxide containing tungsten oxide, indium zinc oxide containing tungsten oxide, indium oxide containing titanium oxide, indium tin oxide containing titanium oxide, indium oxide-zinc oxide, or indium tin oxide to which silicon oxide is added.

Alternatively, as the material of the gate electrode layer 203, an In—Ga—Zn-based oxide containing nitrogen, an In—Sn-based oxide containing nitrogen, an In—Ga-based oxide containing nitrogen, an In—Zn-based oxide containing nitrogen, an Sn-based oxide containing nitrogen, an In-based oxide containing nitrogen, or a metal nitride film (such as an indium nitride film, a zinc nitride film, a tantalum nitride film, or a tungsten nitride film) may be used. These materials have a work function of 5 eV or more. Therefore, when the gate electrode layer 203 is formed using any of these materials, the threshold voltage of the transistor can be positive, so that the transistor can be a normally-off switching transistor. Note that the gate electrode layer 203 can be formed by a sputtering method, a plasma CVD method, a thermal CVD method such as a MOCVD method or an ALD method, or the like.

The insulating layer 204 and the insulating layer 206 serve as the gate insulating layer of the transistor 100. As each of the insulating layer 204 and the insulating layer 206, an insulating layer including at least one of the following films formed by a plasma CVD method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that a structure of the gate insulating layer is not limited to the stacked-layer structure of the insulating layer 204 and the insulating layer 206. An insulating layer with a single-layer structure including any of the above-described films can be used as the gate insulating layer.

Note that the insulating layer 206 that is in contact with the oxide semiconductor layer 208b formed later is preferably an oxide insulating layer and preferably has a region (oxygen-excess region) containing oxygen in excess of the stoichiometric composition. In order to provide the oxygen-excess region in the insulating layer 206, the insulating layer 206 may be formed in an oxygen atmosphere, for example. Alternatively, oxygen may be introduced into the formed insulating film 206 to provide the oxygen-excess region therein. As a method for introducing oxygen, an ion implantation method, an ion doping method, a plasma immersion ion implantation method, plasma treatment, or the like may be employed.

In this embodiment, a silicon nitride layer is formed as the insulating layer 204, and a silicon oxide layer is formed as the insulating layer 206. The relative dielectric constant of the silicon nitride layer is higher than that of the silicon oxide layer, and the silicon nitride layer needs to have a larger film thickness than the silicon oxide layer to obtain an equivalent capacitance. Thus, when the silicon nitride layer is included in the insulating layer 204 serving as the gate insulating layer of the transistor 100, the thickness of the gate insulating layer can be increased. From the above, the electrostatic breakdown of the transistor 100 can be prevented by inhibiting a reduction in the withstand voltage of the transistor 100 and improving the withstand voltage of the transistor. Note that the insulating layer 204 and the insulating layer 206 can be formed by a sputtering method, a plasma CVD method, a thermal CVD method such as a MOCVD method or an ALD method, or the like.

Next, an oxide semiconductor film 208 is formed over the insulating layer 206 (see FIG. 2B). The oxide semiconductor film 208 preferably includes a film represented by an In-M-Zn oxide that contains at least indium (In), zinc (Zn), and M (metal such as Al, Ga, Ge, Y, Zr, Sn, La, Ce, or Hf). Alternatively, both In and Zn are preferably contained. In order to reduce fluctuations in electrical characteristics of the transistors including the oxide semiconductor, the oxide semiconductor preferably contains a stabilizer in addition to In and Zn.

As a stabilizer, gallium (Ga), tin (Sn), hafnium (Hf), aluminum (Al), zirconium (Zr), and the like can be given. As another stabilizer, lanthanoid such as lanthanum (La), cerium (Ce), praseodymium (Pr), neodymium (Nd), samarium (Sin), europium (Eu), gadolinium (Gd), terbium (Tb), dysprosium (Dy), holmium (Ho), erbium (Er), thulium (Tm), ytterbium (Yb), or lutetium (Lu) can be given.

As an oxide semiconductor included in the oxide semiconductor film 208, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn—based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no limitation on the ratio of In:Ga:Zn. The In—Ga—Z-based oxide may contain another metal element in addition to In, Ga, and Zn.

The oxide semiconductor film 208 can be formed by a sputtering method, a molecular beam epitaxy (MBE) method, a CVD method, a pulsed laser deposition method, an atomic layer deposition (ALD) method, or the like as appropriate.

In the formation of the oxide semiconductor film 208, the hydrogen concentration in the oxide semiconductor film is preferably reduced as much as possible. In order to reduce the hydrogen concentration, besides the high vacuum evacuation of the chamber, high purity of a sputtering gas is also needed when film formation is performed by a sputtering method, for example. As an oxygen gas or an argon gas used for a sputtering gas, a gas which is highly purified to have a dew point of −40° C. or lower, preferably −80° C. or lower, further preferably −100° C. or lower, further preferably −120° C. or lower is used, whereby entry of moisture or the like into the oxide semiconductor film 208 can be prevented as much as possible.

In order to remove moisture remaining in the deposition chamber, an entrapment vacuum pump, such as a cryopump, an ion pump, or a titanium sublimation pump, is preferably used. The evacuation unit may be a turbo molecular pump provided with a cold trap. Since a cryopump has a high capability in removing a compound including a hydrogen atom such as a hydrogen molecule and water (H₂O) (preferably, also a compound including a carbon atom), and the like, the concentration of an impurity contained in a film formed in the deposition chamber evacuated with the cryopump can be reduced.

Further, in the case where the oxide semiconductor film 208 is formed by a sputtering method, the relative density (the fill rate) of a metal oxide target which is used for forming the oxide semiconductor film is greater than or equal to 90% and less than or equal to 100%, preferably greater than or equal to 95% and less than or equal to 99.9%. With the use of the metal oxide target having high relative density, a dense oxide film can be formed.

Note that formation of the oxide semiconductor film 208 while the substrate 202 is kept at high temperature is also effective in reducing the impurity concentration in the oxide semiconductor film 208. The heating temperature of the substrate 202 may be higher than or equal to 150° C. and lower than or equal to 450° C., and preferably the substrate temperature is higher than or equal to 200° C. and lower than or equal to 350° C.

Next, the oxide semiconductor film 208 is processed into desired shapes, so that an island-shaped oxide semiconductor layer 208d and the oxide semiconductor layer 208b are formed (see FIG. 2C). When the oxide semiconductor film 208 is processed by etching, a part of the insulating layer 206 (a region not covered with the oxide semiconductor layer 208a and the oxide semiconductor layer 208b) might be etched to be thinned because of overetching of the oxide semiconductor film 208.

After the island-shaped oxide semiconductor layer 208d and the oxide semiconductor layer 208b are formed, heat treatment is performed. The heat treatment is preferably performed at a temperature of higher than or equal to 250° C. and lower than or equal to 650° C., preferably higher than or equal to 300° C. and lower than or equal to 400° C., more preferably higher than or equal to 320° C. and lower than or equal to 370° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen. By the heat treatment, an impurity such as hydrogen or water can be removed from at least one of the insulating layer 204, the insulating layer 206, the oxide semiconductor layer 208d, and the oxide semiconductor layer 208b. Note that the heat treatment may be performed before the oxide semiconductor film 208 is processed into an island shape.

Note that stable electrical characteristics can be effectively imparted to the transistor 100 in which an oxide semiconductor serves as a channel by reducing the concentration of impurities in the oxide semiconductor to make the oxide semiconductor intrinsic or substantially intrinsic.

Next, an oxide insulating film 210a is formed over the oxide semiconductor layer 208d and the oxide semiconductor layer 208b (see FIG. 2D).

As the oxide insulating film 210a, a silicon oxide film, a silicon oxynitride film, an aluminum oxide film, or the like having a thickness of from 150 nm to 400 nm can be used, for example. In this embodiment, a 300-nm-thick silicon oxynitride film is used as the oxide insulating film 210a. The oxide insulating film 210a can be formed by a CVD method, for example.

Then, the oxide insulating film 210a is processed into desired shapes, so that an opening portion 302 is formed. The oxide insulating film 210a serves as the oxide insulating layer 210 where the opening portion 302 is formed.

The opening portion 302 is formed so as to expose the oxide semiconductor layer 208a. An example of a formation method of the opening portion 302 includes, but not limited to, a dry etching method. Alternatively, a wet etching method or a combination of dry etching and wet etching can be employed for formation of the opening portion 302. By the etching step for forming the opening portion 302, a part of the insulating layer 206 that is not covered with the oxide insulating layer 210 and the oxide semiconductor layer 208a are thinned in some cases.

Then, heat treatment is preferably performed. By the heat treatment, part of oxygen contained in the oxide insulating layer 210 can be moved to the oxide semiconductor layer 208b, so that oxygen vacancies in the oxide semiconductor layer 208b can be filled. Consequently, oxygen vacancies in the oxide semiconductor layer 208b can be reduced, while oxygen vacancies in the oxide semiconductor layer 208d that is not in contact with the oxide insulating layer 210 are not reduced. Thus, the amount of oxygen vacancies in the oxide semiconductor layer 208d is larger than that of oxygen vacancies in the oxide semiconductor layer 208b. The heat treatment can be performed under conditions similar to those for the heat treatment performed after the formation of the oxide semiconductor layer 208d and the oxide semiconductor layer 208b.

Next, the nitride insulating layer 212 is formed over the oxide insulating layer 210 and the oxide semiconductor layer 208d (see FIG. 3B).

The nitride insulating layer 212 contains hydrogen. When hydrogen contained in the nitride insulating layer 212 diffuses into the oxide semiconductor layer 208d, hydrogen is bonded to an oxygen vacancy in the oxide semiconductor layer 208d, thereby producing an electron serving as a carrier. As a result, the oxide semiconductor layer 208d becomes the oxide semiconductor layer 208a with low resistance. The resistivity of the oxide semiconductor layer 208a is lower than at least the resistivity of the oxide semiconductor layer 208b and is preferably higher than or equal to 1×10⁻³ Ωcm and lower than 1×10⁴ Ωcm, further preferably higher than or equal to 1×10⁻³ Ωcm and lower than 1×10⁻¹ Ωcm. Note that the nitride insulating layer 212 also has an advantageous effect of preventing an external impurity such as water, alkali metal, or alkaline earth metal, from diffusing into the oxide semiconductor layer 208b included in the transistor 100. The nitride insulating layer 212 can be formed by a sputtering method, a plasma CVD method, a thermal CVD method such as a MOCVD method or an ALD method, or the like.

In this embodiment, the process in which hydrogen is supplied from the nitride insulating layer 212 covering the oxide semiconductor layer 208d is described, but the present invention is not limited to this process. For example, a mask can be formed in a region that is to serve as a channel formation region of the transistor 100, and a region not covered with the mask can be supplied with hydrogen. As another example, an ion doping apparatus or the like can be used to introduce hydrogen into the oxide semiconductor layer 208d. Further, treatment in a plasma atmosphere containing hydrogen may be performed on the oxide semiconductor layer 208d to introduce hydrogen. Alternatively, treatment in a plasma atmosphere containing hydrogen and argon may be performed on the oxide semiconductor layer 208d to introduce hydrogen.

For example, a silicon nitride film, a silicon nitride oxide film, or the like having a thickness of from 100 nm to 400 nm can be used as the nitride insulating layer 212. In this embodiment, a silicon nitride layer having a thickness of 150 nm is used as the nitride insulating layer 212.

The silicon nitride layer is preferably formed at a high temperature to have an improved blocking property; for example, the silicon nitride layer is preferably formed at a temperature in the range from the substrate temperature of 100° C. to the strain point of the substrate, more preferably at a temperature in the range from 300° C. to 400° C. When the silicon nitride layer is formed at a high temperature, a phenomenon in which oxygen is released from the oxide semiconductor layer 208b and the carrier density is increased is caused in some cases; therefore, the upper limit of the temperature is a temperature at which the phenomenon is not caused.

Next, opening portions reaching the oxide semiconductor layer 208a and the oxide semiconductor layer 208b are formed in the nitride insulating layer 212 and the oxide insulating layer 210. A conductive film is formed over the opening portions and the nitride insulating layer 212 and processed, so that the electrode layer 214a, the electrode layer 214b, the electrode layer 214c, and the electrode layer 214d are formed (see FIG. 3C).

The conductive film that is to be the electrode layers 214a to 214d can be formed with a single-layer structure or a stacked-layer structure using any of single metals such as aluminum, titanium, chromium, nickel, copper, yttrium, zirconium, molybdenum, silver, tantalum, and tungsten, or an alloy containing any of these single metals as its main component. For example, a two-layer structure in which a titanium film is stacked over an aluminum film, a two-layer structure in which a titanium film is stacked over a tungsten film, a two-layer structure in which a copper film is formed over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used. The conductive film can be formed by a sputtering method, a plasma CVD method, a thermal CVD method such as a MOCVD method or an ALD method, or the like.

Note that the contact holes reaching the oxide semiconductor layer 208a in the resistor 150 and the contact holes reaching the oxide semiconductor layer 208b in the transistor 100 can be formed by a single etching step. However, in some cases, a part of the oxide semiconductor layer 208a is overetched by etching of the oxide insulating layer 210 for forming the contact holes that reach the oxide semiconductor layer 208b. Thus, in some cases, the thickness of each of the regions of the oxide semiconductor layer 208a that are in contact with the electrode layer 214a and the electrode layer 214b is smaller than the thickness of each of the regions of the oxide semiconductor layer 208b that are in contact with the electrode layer 214c and the electrode layer 214d. Further, in some cases, the thickness of each of the regions of the oxide semiconductor layer 208a that are in contact with the electrode layer 214a and the electrode layer 214b is smaller than the thickness of the region of the oxide semiconductor layer 208a that is in contact with the nitride insulating layer 212.

Further, in some cases, a part of the oxide semiconductor layer 208b is overetched by the formation of the contact holes reaching the oxide semiconductor layer 208b. Thus, in some cases, the thickness of each of the regions of the oxide semiconductor layer 208b that are in contact with the electrode layer 214c and the electrode layer 214d is smaller than the thickness of the region of the oxide semiconductor layer 208b that is in contact with the oxide insulating layer 210. Further, regions not subjected to the etching step, namely, the region of the oxide semiconductor layer 208a that is in contact with the nitride insulating layer 212 and the region of the oxide semiconductor layer 208b that is in contact with the oxide insulating layer 210 have similar thicknesses in some cases.

Through the above-described process, the transistor 100 of a channel-protection type and the resistor 150 can be formed over the same substrate.

In the resistor 150 obtained by the manufacturing process described in this embodiment, the nitride insulating layer 212 serving as a hydrogen supply source is provided to cover an entire surface of the island-shaped oxide semiconductor layer 208a, so that the resistance of the whole of the oxide semiconductor layer 208a can be lowered. Thus, in the oxide semiconductor layer 208a, the region in contact with the nitride insulating layer 212 and the regions in contact with the electrode layer 214a and the electrode layer 214b in the contact holes provided in the nitride insulating layer 212 have the same conductivity and similar resistivities. Consequently, the resistance of the resistor 150 can be adjusted to an appropriate value with high controllability.

The oxide semiconductor layer 208b included in the transistor 100 and the oxide semiconductor layer 208a included in the resistor 150 can be formed by the same film formation step and the same etching step, and further, the oxide semiconductor layers 208b and 208a can have different carrier densities by the influence of the insulating layers in contact with the upper surfaces of the oxide semiconductor layers. Thus, the number of steps of forming a semiconductor device can be reduced. The amount of oxygen vacancies in the oxide semiconductor layer 208a in which the oxygen vacancies are not filled using the oxide insulating layer 210 is larger than that in at least the oxide semiconductor layer 208b. The hydrogen concentration of the oxide semiconductor layer 208a that is supplied with hydrogen from the nitride insulating layer 212 is higher than that of at least the oxide semiconductor layer 208b. Hence, the oxide semiconductor layer 208a has a higher carrier density and a lower resistance than at least the oxide semiconductor layer 208b.

The highly purified intrinsic or substantially highly purified intrinsic oxide semiconductor layer 208b obtained by reducing the hydrogen concentration and filling the oxygen vacancies can have a carrier density of lower than 1×10¹⁷/cm³, for example. The carrier density of the oxide semiconductor layer 208a including a larger amount of oxygen vacancies and a higher hydrogen concentration than the oxide semiconductor layer 208b can be higher than or equal to 1×10¹⁸/cm³, for example.

Note that the oxide insulating layer 210 and the nitride insulating layer 212 also serve as channel protection films in the transistor 100.

### Modification Example 1

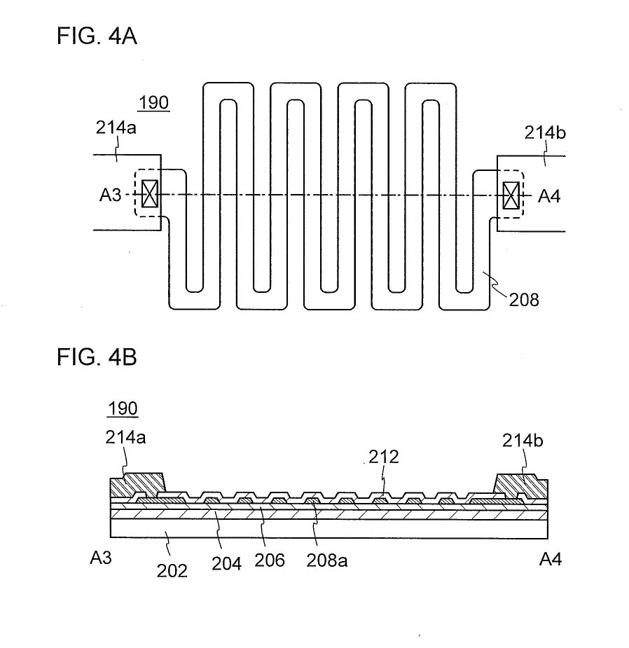

FIGS. 4A and 4B show a modification example of the resistor 150 that can be used for the semiconductor device. FIG. 4A is a plan view of a resistor 190, and FIG. 4B is a cross-sectional view taken along line A3-A4 of FIG. 4A.

The resistor 190 shown in FIGS. 4A and 4B is different from the resistor 150 shown in FIGS. 1A to 1C in the shape of the oxide semiconductor layer 208a. Specifically, the oxide semiconductor layer 208a of the resistor 190 has a serpentine shape in a plan view, instead of the island shape of the oxide semiconductor layer 208a of the resistor 150. Thus, in the resistor 190, the length of a path through which carriers flow in the oxide semiconductor layer 208a can be increased as compared to the island-shaped oxide semiconductor layer 208a. By setting the resistivity of the oxide semiconductor layer 208a and the length of the path through which carriers flow in the oxide semiconductor layer 208a as appropriate, a resistor having an appropriate resistance can be obtained.

The length of the path through which carriers flow in the oxide semiconductor layer 208a of the resistor 190 is preferably longer than the length of a path through which carriers flow in the oxide semiconductor layer 208b, i.e., a channel length, of the transistor 100 (not shown). Note that in FIGS. 4A and 4B, the oxide semiconductor layer 208a has a serpentine shape in a plan view but not limited thereto. The oxide semiconductor layer 208a may have a shape with straight lines and a corner, a curved shape, or the like in a plan view to adjust the length of the path through which carriers flow in the oxide semiconductor layer 208a.

Note that the description of the resistor 150 can be referred to for the resistor 190 except the shape of the oxide semiconductor layer 208a.

### Modification Example 2

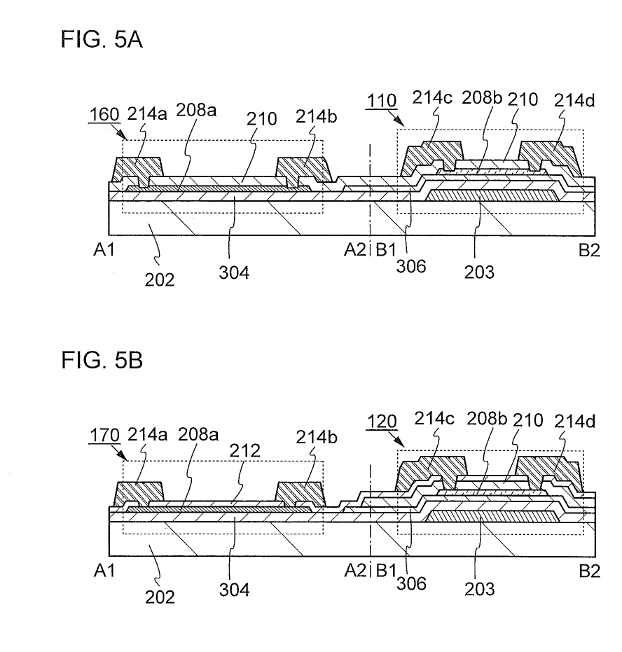

FIG. 5A shows a modification example of the transistor and the resistor in the semiconductor device. A resistor 160 shown in FIG. 5A includes a nitride insulating layer 304 provided over the substrate 202, the oxide semiconductor layer 208a that is over and in contact with the nitride insulating layer 304, the oxide insulating layer 210 covering the oxide semiconductor layer 208a, and the electrode layer 214a and the electrode layer 214b that are electrically connected to the oxide semiconductor layer 208a in contact holes provided in the oxide insulating layer 210. The oxide semiconductor layer 208a included in the resistor 160 is an oxide semiconductor layer whose resistance is lowered by the supply of hydrogen from the nitride insulating layer 304 provided in contact with the lower surface of the oxide semiconductor layer 208a.

A transistor 110 shown in FIG. 5A includes the gate electrode layer 203 provided over the substrate 202, the nitride insulating layer 304 over the gate electrode layer 203, an oxide insulating layer 306 over the nitride insulating layer 304, the oxide semiconductor layer 208b over the oxide insulating layer 306, the oxide insulating layer 210 over the oxide semiconductor layer 208b, and the electrode layer 214c and the electrode layer 214d that are electrically connected to the oxide semiconductor layer 208b in the contact holes provided in the oxide insulating layer 210.

The nitride insulating layer 304 and the oxide insulating layer 210 are shared by the resistor 160 and the transistor 110. Note that in the transistor 110, the nitride insulating layer 304 and the oxide insulating layer 306 serve as a gate insulating layer. In the semiconductor device shown in FIG. 5A, after the oxide insulating layer 306 serving as a part of the gate insulating layer of the transistor 110 is formed, the oxide insulating layer 306 is selectively etched to remove a region of the oxide insulating layer 306 that overlaps the oxide semiconductor layer 208a. Thus, the nitride insulating layer 304 serving as a part of the gate insulating layer of the transistor 110 can be in contact with the oxide semiconductor layer 208a included in the resistor 160.

Note that in the resistor 160 and the transistor 110, the nitride insulating layer 212 may be found over the oxide insulating layer 210 as a blocking layer.

Note that FIG. 5A shows, as an example, the case where a part of the oxide semiconductor layer 208a and a part of the oxide semiconductor layer 208b are overetched by etching of the oxide insulating layer 210 for forming the contact holes reaching the oxide semiconductor layer 208a and the oxide semiconductor layer 208b. In FIG. 5A, the thickness of each of regions of the oxide semiconductor layer 208a that are in contact with the electrode layer 214a and the electrode layer 214b is smaller than the thickness of a region of the oxide semiconductor layer 208a that is in contact with the oxide insulating layer 210. Further, the thickness of each of regions of the oxide semiconductor layer 208b that are in contact with the electrode layer 214c and the electrode layer 214d is smaller than the thickness of a region of the oxide semiconductor layer 208b that is in contact with the oxide insulating layer 210. Note that the thickness of the region of the oxide semiconductor layer 208a that is in contact with the oxide insulating layer 210 is equal to the thickness of the region of the oxide semiconductor layer 208b that is in contact with the oxide insulating layer 210. Further, the thickness of each of the regions of the oxide semiconductor layer 208a that are in contact with the electrode layer 214a and the electrode layer 214b is equal to the thickness of each of the regions of the oxide semiconductor layer 208b that are in contact with the electrode layer 214c and the electrode layer 214d.

In the structure of the resistor 160 shown in FIG. 5A, hydrogen is supplied from the nitride insulating layer 304 provided in contact with the entire lower surface of the oxide semiconductor layer 208a, whereby the resistance of the whole of the oxide semiconductor layer 208a can be lowered. The resistor 160 shown in FIG. 5A can be formed with the same number of masks used for forming the resistor 150 shown in FIGS. 1A to 1C.

### Modification Example 3

FIG. 5B shows a modification example of the resistor and the transistor that are included in the semiconductor device. A resistor 170 shown in FIG. 5B includes the nitride insulating layer 304 provided over the substrate 202, the oxide semiconductor layer 208a that is over and in contact with the nitride insulating layer 304, the nitride insulating layer 212 covering the oxide semiconductor layer 208a, and the electrode layer 214a and the electrode layer 214b that are electrically connected to the oxide semiconductor layer 208a in the contact holes provided in the nitride insulating layer 212. That is, the oxide semiconductor layer 208a included in the resistor 170 is an oxide semiconductor layer whose resistance is reduced by the supply of hydrogen from both the nitride insulating layer 304 provided in contact with the lower surface of the oxide semiconductor layer 208a and the nitride insulating layer 212 provided in contact with the upper surface of the oxide semiconductor layer 208a.

A transistor 120 shown in FIG. 5B includes the gate electrode layer 203 provided over the substrate 202, the nitride insulating layer 304 over the gate electrode layer 203, the oxide insulating layer 306 over the nitride insulating layer 304, the oxide semiconductor layer 208b over the oxide insulating layer 306, the oxide insulating layer 210 over the oxide semiconductor layer 208b, the nitride insulating layer 212 over the oxide insulating layer 210, and the electrode layer 214c and the electrode layer 214d that are electrically connected to the oxide semiconductor layer 208b in the contact holes provided in the nitride insulating layer 212 and the oxide insulating layer 210. That is, the transistor 120 has a structure in which the nitride insulating layer 304 and the oxide insulating layer 306 are provided as the insulating layer 204 and the insulating layer 206, respectively, in the transistor 100.

In the semiconductor device shown in FIG. 5B, the oxide semiconductor layer 208a included in the resistor 170 is supplied with hydrogen from both the upper side and the lower side of the oxide semiconductor layer 208a, whereby the carrier density of the oxide semiconductor layer 208a can be sufficiently different from the carrier density of the oxide semiconductor layer 208b. The structure in which hydrogen is supplied from both the upper side and the lower side of the oxide semiconductor layer 208a is effective depending on the needed resistance of the resistor. Note that the oxide semiconductor layer 208a can be used as a part of a wiring depending on the resistivity of the oxide semiconductor layer 208a.

### Modification Example 4

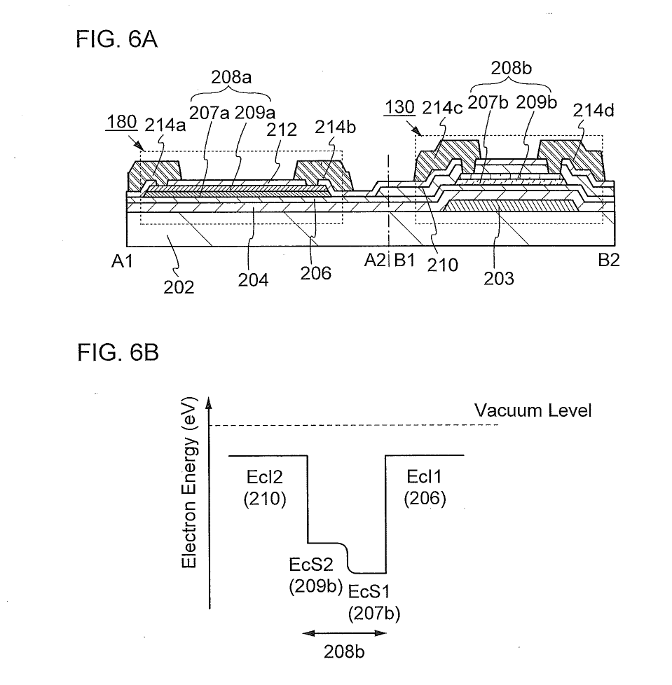

FIG. 6A shows a modification example of the resistor and the transistor that are included in the semiconductor device. A resistor 180 shown in FIG. 6A is an example in which a stacked-layer structure of an oxide semiconductor layer 207a and an oxide semiconductor layer 209a is used instead of the oxide semiconductor layer 208a in the resistor 150. The other components of the resistor 180 are the same as those of the resistor 150; hence, the above description can be referred to.

A transistor 130 shown in FIG. 6A is an example in which a stacked-layer structure of an oxide semiconductor layer 207b and an oxide semiconductor layer 209b is used instead of the oxide semiconductor layer 208b in the transistor 100. The other components of the transistor 130 are the same as those of the transistor 100; hence, the above description can be referred to.

Metal oxide of the oxide semiconductor layers 207a and 207b (in this specification below, also referred to as oxide semiconductor layer 207) and metal oxide of the oxide semiconductor layers 209a and 209b (in this specification below, also referred to as oxide semiconductor layer 209) preferably have at least one constituent element in common. Further, the constituent elements of the oxide semiconductor layer 207 and the oxide semiconductor layer 209 are made to be the same and the composition of the constituent elements of the oxide semiconductor layer 207 and the oxide semiconductor layer 209 may be made to be different.

In the case where the oxide semiconductor layer 207 is In-M-Zn oxide (M represents Al, Ga, Ge, Y, Zr, Sn, La, Ce, or Hf), it is preferable that the atomic ratio of metal elements of a sputtering target used for forming a film of the In-M-Zn oxide satisfy In≧M and Zn≧M. As the atomic ratio of metal elements of such a sputtering target, In:MZn=1:1:1 and In:M:Zn=3:1:2 are preferable. Note that the proportion of the atomic ratio of the oxide semiconductor layer 207 formed using the above-described sputtering target varies within a range of ±20% as an error.

In the case of using In-M-Zn oxide for the oxide semiconductor layer 207, when Zn and O are eliminated from consideration, the proportion of In and the proportion of M are preferably greater than or equal to 25 atomic % and less than 75 atomic %, respectively, further preferably greater than or equal to 34 atomic % and less than 66 atomic %, respectively.

The energy gap of the oxide semiconductor layer 207 is 2 eV or more, preferably 2.5 eV or more, further preferably 3 eV or more. In this manner, off-state current of a transistor can be reduced by using an oxide semiconductor having an energy gap.

The thickness of the oxide semiconductor layer 207 is greater than or equal to 3 nm and less than or equal to 200 nm, preferably greater than or equal to 3 nm and less than or equal to 100 nm, more preferably greater than or equal to 3 nm and less than or equal to 50 nm.

The oxide semiconductor layer 209 is typically In—Ga oxide, In—Zn oxide, or In-M-Zn oxide (M represents Al, Ga, Ge, Y, Zr, Sn, La, Ce, or Hf). The energy at the conduction band bottom thereof is closer to a vacuum level than that of the oxide semiconductor layer 207 is, and typically, the difference between the energy at the conduction band bottom of the oxide semiconductor layer 209 and the energy at the conduction band bottom of the oxide semiconductor layer 207 is any one of 0.05 eV or more, 0.07 eV or more, 0.1 eV or more, and 0.15 eV or more, and any one of 2 eV or less, 1 eV or less, 0.5 eV or less, and 0.4 eV or less. That is, the difference between the electron affinity of the oxide semiconductor layer 209 and the electron affinity of the oxide semiconductor layer 207 is any one of 0.05 eV or more, 0.07 eV or more, 0.1 eV or more, and 0.15 eV or more, and any one of 2 eV or less, 1 eV or less, 0.5 eV or less, and 0.4 eV or less.

When the oxide semiconductor layer 209 contains a larger amount of the element M in an atomic ratio than the amount of In in an atomic ratio, any of the following effects may be obtained:

(1) the energy gap of the oxide semiconductor layer 209 is widened;
(2) the electron affinity of the oxide semiconductor layer 209 decreases;
(3) an impurity from the outside is blocked; and
(4) an insulating property increases as compared to the oxide semiconductor layer 207. Further, oxygen vacancies are less likely to be generated in the oxide semiconductor layer 209 containing a larger amount of M in an atomic ratio than the amount of In in an atomic ratio because M is a metal element which is strongly bonded to oxygen.

For example, in the case of using In-M-Zn oxide for the oxide semiconductor layer 209, when Zn and O are eliminated from consideration, the proportion of In and the proportion of M are preferably less than 50 atomic % and greater than or equal to 50 atomic %, respectively, further preferably less than 25 atomic % and greater than or equal to 75 atomic %, respectively.

Further, in the case where each of the oxide semiconductor layer 207 and the oxide semiconductor layer 209 is In-M-Zn oxide (M represents Al, Ga, Ge, Y, Zr, Sn, La, Ce, or Hf), the proportion of M atoms in the oxide semiconductor layer 209 is higher than the proportion of M atoms in the oxide semiconductor layer 207. Typically, the proportion of M atoms in the oxide semiconductor layer 209 is higher than or equal to 1.5 times, preferably higher than or equal to 2 times, further preferably higher than or equal to 3 times as large as that in the oxide semiconductor layer 207.

In the case where the oxide semiconductor layer 209 has an atomic ratio of In to M and Zn which is x₁:y₁:z₁ and the oxide semiconductor layer 207 has an atomic ratio of In to M and Zn which is x₂:y₂:z₂, y₁/x₁ is larger than y₂/x₂, preferably y₁/x₁ is 1.5 times or more as large as y₂/x₂. It is further preferable that y₁/x₁ be twice or more as large as y₂/x₂. It is still further preferable that y₁/x₁ be three or more times as large as y₂/x₂. In this case, it is preferable that in the oxide semiconductor layer, y₂ be higher than or equal to x₂ because the transistor 130 including the oxide semiconductor layer can have stable electric characteristics. However, when y₂ is larger than or equal to three or more times x₂, the field-effect mobility of the transistor 130 including the oxide semiconductor layer is reduced. Thus, it is preferable that y₂ be lower than three times x₂.

Further, in the case where the oxide semiconductor layer 209 is In-M-Zn oxide, the atomic ratio of metal elements of a sputtering target used for forming the In-M-Zn oxide preferably satisfies M>In and Zn>0.5×M, and more preferably, Zn also satisfies Zn>M. As the atomic ratio of metal elements of such a sputtering target, In:Ga:Zn=1:3:2, In:Ga:Zn=1:3:4, In:Ga:Zn=1:3:5, In:Ga:Zn=1:3:6, In:Ga:Zn=1:3:7, In:Ga:Zn=1:3:8, In:Ga:Zn=1:3:9, In:Ga:Zn=1:3:10, In:Ga:Zn=1:6:4, In:Ga:Zn=1:6:5, In:Ga:Zn=1:6:6, In:Ga:Zn=1:6:7, In:Ga:Zn=1:6:8, In:Ga:Zn=1:6:9, and In:Ga:Zn=1:6:10 are preferable. Note that the proportion of each metal element in the atomic ratio of each of the oxide semiconductor layer 207 and the oxide semiconductor layer 209 formed using the above-described sputtering target varies within a range of ±20% as an error.

Note that, without limitation to those described above, a material with an appropriate composition may be used depending on required semiconductor characteristics and electrical characteristics (e.g., field-effect mobility and threshold voltage) of a transistor. Further, in order to obtain the required semiconductor characteristics of the transistor, it is preferable that the carrier density, the impurity concentration, the defect density, the atomic ratio of a metal element to oxygen, the interatomic distance, the density, and the like of the oxide semiconductor layer 207 be set to appropriate values.

The oxide semiconductor layer 209 also serves as a film that relieves damage to the oxide semiconductor layer 207 at the time of forming the oxide insulating layer 210 or the nitride insulating layer 212 later. The thickness of the oxide semiconductor layer 209 is greater than or equal to 3 nm and less than or equal to 100 nm, preferably greater than or equal to 3 nm and less than or equal to 50 nm.

When silicon or carbon which is one of elements belonging to Group 14 is contained in the oxide semiconductor layer 207b in the transistor 130, the number of oxygen vacancies is increased, and the oxide semiconductor layer 207b is changed to an n-type. Thus, the concentration of silicon or carbon (the concentration is measured by SIMS) in the oxide semiconductor layer 207b or the concentration of silicon or carbon (the concentration is measured by SIMS) in the vicinity of the interface between the oxide semiconductor layer 209b and the oxide semiconductor layer 207b is set to be lower than or equal to 2×10¹⁸ atoms/cm³, preferably lower than or equal to 2×10¹⁷ atoms/cm³.

Further, the concentration of alkali metal or alkaline earth metal of the oxide semiconductor layer 207b, which is measured by SIMS, is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal of the oxide semiconductor layer 207b.

Further, when nitrogen is contained in the oxide semiconductor layer 207b, electrons serving as carriers are generated to increase the carrier density, so that the oxide semiconductor layer 207b easily becomes n-type. Thus, a transistor including an oxide semiconductor which contains nitrogen is likely to be normally on. For this reason, nitrogen in the oxide semiconductor layer is preferably reduced as much as possible; the concentration of nitrogen which is measured by SIMS is preferably set to, for example, lower than or equal to 5×10¹⁸ atoms/cm³.

Note that in the transistor 130 shown in FIG. 6A, the oxide semiconductor layer 209 is provided between the oxide semiconductor layer 207 and the oxide insulating layer 210. The oxide semiconductor layer 207 is positioned on the gate electrode layer 203 side and serves as a main path of carriers. Thus, if trap states due to impurities and defects are formed between the oxide semiconductor layer 209 and the oxide insulating layer 210, electrons flowing in the oxide semiconductor layer 207 are less likely to be captured by the trap states because there is a distance between the trap states and the oxide semiconductor layer 207. Accordingly, the amount of on-state current of the transistor 130 can be increased, and the field-effect mobility can be increased. When the electrons are captured by the trap states, the electrons become negative fixed charges. Consequently, a threshold voltage of the transistor 130 fluctuates. However, by the distance between the oxide semiconductor layer 207 and the trap states, capture of the electrons by the trap states can be reduced, and accordingly a fluctuation of the threshold voltage can be reduced.

Note that the oxide semiconductor layer 207 and the oxide semiconductor layer 209 are not formed by simply stacking the layers, but are formed to form a continuous junction (here, in particular, a structure in which the energy of the bottom of the conduction band is changed continuously between the layers). In other words, the oxide semiconductor layer 207 and the oxide semiconductor layer 209 have a stacked structure such that there exist no impurities which form a defect level such as a trap center or a recombination center, or a barrier inhibiting carrier flow at the interface between the layers. If an impurity exists between the oxide semiconductor layer 207 and the oxide semiconductor layer 209 which are stacked, a continuity of the energy band is damaged, and the carrier is captured or recombined at the interface and then disappears.

In order to form such a continuous energy band, it is necessary to form layers continuously without being exposed to air, with use of a multi-chamber deposition apparatus (sputtering apparatus) including a load lock chamber. It is preferable that each chamber of the sputtering apparatus be evacuated to a high vacuum (to the degree of approximately higher than or equal to 5×10⁻⁷ Pa and lower than or equal to 1×10⁻⁴ Pa) by an adsorption vacuum pump such as a cryopump so that water and the like acting as impurities of the oxide semiconductor layer are removed as much as possible. Alternatively, a turbo molecular pump and a cold trap are preferably combined so as to prevent a backflow of a gas, especially a gas containing carbon or hydrogen from an exhaust system to the inside of the chamber.

Next, a band structure of the stacked-layer structure included in the transistor 130 is described with reference to FIG. 6B.

FIG. 6B schematically shows a part of a band structure of the transistor 130. Here, the case where silicon oxide layers are provided as the insulating layer 206 and the oxide insulating layer 210 is shown. In FIG. 6B, EcI1 denotes the energy of the bottom of the conduction band in the silicon oxide layer used as the insulating layer 206; EcS1 denotes the energy of the bottom of the conduction band in the oxide semiconductor layer 207b; EcS2 denotes the energy of the bottom of the conduction band in the oxide semiconductor layer 209b; and EcI2 denotes the energy of the bottom of the conduction band in the silicon oxide layer used as the oxide insulating layer 210.

As illustrated in FIG. 6B, there is no energy barrier between the oxide semiconductor layer 207b and the oxide semiconductor layer 209b, and the energy level of the bottom of the conduction band gradually changes therebetween. In other words, the energy level of the bottom of the conduction band is continuously changed. This is because the oxide semiconductor layer 207b contains an element contained in the oxide semiconductor layer 209b and oxygen is transferred between the oxide semiconductor layer 207b and the oxide semiconductor layer 209b, so that a mixed layer is foamed.

As shown in FIG. 6B, the oxide semiconductor layer 207b in the oxide semiconductor layer 208b serves as a well and a channel region of the transistor including the oxide semiconductor layer 208b is formed in the oxide semiconductor layer 207. Note that since the energy of the bottom of the conduction band of the oxide semiconductor layer 208b is continuously changed, it can be said that the oxide semiconductor layer 207b and the oxide semiconductor layer 209b are continuous.

Although trap states due to impurities or defects, which are derived from silicon, carbon, or the like as a constituent element of the oxide insulating layer 210, are likely to be formed in the vicinity of the interface between the oxide semiconductor layer 209b and the oxide insulating layer 210 as illustrated in FIG. 6B, the oxide semiconductor layer 207b can be distanced from the trap states owing to existence of the oxide semiconductor layer 209. However, when the energy difference between EcS1 and EcS2 is small, an electron in the oxide semiconductor layer 207b might reach the trap level by passing over the energy difference. When the electron is captured by the trap state, negative fixed electric charge are generated at or in the vicinity of the interface between the oxide insulating layers, so that the threshold voltage of the transistor is shifted to the positive side. Therefore, it is preferable that the energy difference between EcS1 and EcS2 be 0.1 eV or more, more preferably 0.15 eV or more because a change in the threshold voltage of the transistor is prevented and stable electrical characteristics are obtained.

Note that FIGS. 6A and 6B show an example where the oxide semiconductor layers in the resistor 150 and the transistor 100 shown in FIGS. 1A to 1C each have a stacked-layer structure. However, this embodiment is not particularly limited thereto. The oxide semiconductor layer in any of the semiconductor devices with the structures shown in FIGS. 4A and 4B, FIG. 5A, and FIG. 5B may have a stacked-layer structure.

The structural examples of the semiconductor devices in this embodiment are partly different from one another. However, one embodiment of the present invention is not particularly limited to any of the structures, and a variety of combinations of the structures are possible. For example, in the oxide semiconductor layer with a stacked-layer structure shown in FIG. 6A, the thickness of a region in contact with the electrode layer may be smaller than the thickness of a region in contact with the oxide insulating layer or the nitride insulating layer.

As described above, the semiconductor device in this embodiment includes the resistor having the oxide semiconductor layer and the transistor having the oxide semiconductor layer over the same substrate. The impurity concentration of each of the oxide semiconductor layers is controlled with the use of the insulating layer being in contact with the upper surface or the lower surface of each of the oxide semiconductor layers, so that the oxide semiconductor layers have different carrier densities. Specifically, the oxide semiconductor layer included in the resistor has a high carrier density because the resistance of the oxide semiconductor layer is reduced by the supply of hydrogen from the nitride insulating layer being in contact with the entire upper surface or the entire lower surface of the oxide semiconductor layer. The oxide semiconductor layer included in the transistor has a low carrier density in which oxygen vacancies are reduced and the resistance is thus increased by the supply of oxygen from the oxide insulating layer being in contact with at least the upper surface of the oxide semiconductor layer.

The structures, the methods, and the like described in this embodiment can be combined as appropriate with any of the structures, the methods, and the like described in the other embodiments.

### Embodiment 2

In this embodiment, an example of an oxide semiconductor layer that can be used for the transistor and the resistor in Embodiment 1 is described.

### <Crystallinity of Oxide Semiconductor Layer>

A structure of an oxide semiconductor layer is described below.

An oxide semiconductor layer is classified roughly into a non-single-crystal oxide semiconductor layer and a single crystal oxide semiconductor layer. The non-single-crystal oxide semiconductor layer includes a c-axis aligned crystalline oxide semiconductor (CAAC-OS) film, a polycrystalline oxide semiconductor layer, a microcrystalline oxide semiconductor layer, an amorphous oxide semiconductor layer, and the like.

First, a CAAC-OS film is described.

The CAAC-OS film is one of oxide semiconductor layers including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “perpendicular” indicates that the angle formed between two straight lines ranges from 80° to 100°, and accordingly includes the case where the angle ranges from 85° to 95°.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 28 is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor layer of InGaZnO₄, six peaks appear. The six peaks are derived from crystal planes equivalent to the (110) plane. On the other hand, in the case of a CAAC-OS film, a peak is not clearly observed even when φ scan is performed with 28 fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is foil red concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appears at around 31° and a peak of 2θ do not appear at around 36°.

In this specification, the trigonal and rhombohedral crystal systems are included in the hexagonal crystal system.

The CAAC-OS film is an oxide semiconductor layer having a low impurity concentration. The impurity is any of elements which are not the main components of the oxide semiconductor layer and includes hydrogen, carbon, silicon, a transition metal element, and the like. In particular, an element (e.g., silicon) which has higher bonding strength with oxygen than a metal element included in the oxide semiconductor layer causes disorder of atomic arrangement in the oxide semiconductor layer because the element deprives the oxide semiconductor layer of oxygen, thereby reducing crystallinity. Further, a heavy metal such as iron or nickel, argon, carbon dioxide, and the like have a large atomic radius (or molecular radius); therefore, when any of such elements is contained in the oxide semiconductor layer, the element causes disorder of the atomic arrangement of the oxide semiconductor layer, thereby reducing crystallinity. Note that the impurity contained in the oxide semiconductor layer might become a carrier trap or a source of carriers.

The CAAC-OS film is an oxide semiconductor layer having a low density of defect states.

With the use of the CAAC-OS film in a transistor, variation in the electrical characteristics of the transistor due to irradiation with visible light or ultraviolet light is small.

Next, a microcrystalline oxide semiconductor layer will be described.

In an image obtained with a TEM, for example, crystal parts cannot be found clearly in the microcrystalline oxide semiconductor layer in some cases. In most cases, the size of a crystal part included in the microcrystalline oxide semiconductor layer is greater than or equal to 1 nm and less than or equal to 100 nm, or greater than or equal to 1 nm and less than or equal to 10 nm, for example. A microcrystal with a size greater than or equal to 1 nm and less than or equal to 10 nm, or a size greater than or equal to 1 nm and less than or equal to 3 nm is specifically referred to as nanocrystal (nc). An oxide semiconductor layer including nanocrystal is referred to as an nc-OS (nanocrystalline oxide semiconductor) film. In an image obtained with TEM, a crystal grain cannot be found clearly in the nc-OS film in some cases.

In the nc-OS film, a microscopic region (for example, a region with a size greater than or equal to 1 nm and less than or equal to 10 nm, in particular, a region with a size greater than or equal to 1 nm and less than or equal to 3 nm) has a periodic atomic order. Note that there is no regularity of crystal orientation between different crystal parts in the nc-OS film. Thus, the orientation of the whole film is not observed. Accordingly, in some cases, the nc-OS film cannot be distinguished from an amorphous oxide semiconductor layer depending on an analysis method. For example, when the nc-OS film is subjected to structural analysis by an out-of-plane method with an XRD apparatus using an X-ray having a diameter larger than that of a crystal part, a peak which shows a crystal plane does not appear. Further, a halo pattern is shown in a selected-area electron diffraction pattern of the nc-OS film obtained by using an electron beam having a probe diameter (e.g., larger than or equal to 50 nm) larger than a diameter of a crystal part. Meanwhile, spots are shown in a nanobeam electron diffraction pattern of the nc-OS film obtained by using an electron beam having a probe diameter (e.g., larger than or equal to 1 nm and smaller than or equal to 30 nm) close to, or smaller than or equal to the diameter of a crystal part. Further, in a nanobeam electron diffraction pattern of the nc-OS film, regions with high luminance in a circular (ring) pattern are observed in some cases. Also in a nanobeam electron diffraction pattern of the nc-OS film, a plurality of spots are shown in a ring-like region in some cases.

Since the nc-OS film is an oxide semiconductor layer having more regularity than the amorphous oxide semiconductor layer, the nc-OS film has a lower density of defect states than the amorphous oxide semiconductor layer. Note that there is no regularity of crystal orientation between different crystal parts in the nc-OS film; hence, the nc-OS film has a higher density of defect states than the CAAC-OS film.

Note that an oxide semiconductor layer may be a stacked film including two or more films of an amorphous oxide semiconductor layer, a microcrystalline oxide semiconductor layer, and a CAAC-OS film, for example.

### <Formation Method of CAAC-OS Film>

For example, the CAAC-OS film is formed by a sputtering method with a polycrystalline oxide semiconductor sputtering target. When ions collide with the sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle reaches a substrate while maintaining their crystal state, whereby the CAAC-OS film can be formed.

The flat-plate-like sputtered particle has, for example, an equivalent circle diameter of a plane parallel to the a-b plane of greater than or equal to 3 nm and less than or equal to 10 nm, and a thickness (length in the direction perpendicular to the a-b plane) of greater than or equal to 0.7 nm and less than 1 nm. Note that in the flat-plate-like sputtered particle, the plane parallel to the a-b plane may be a regular triangle or a regular hexagon. Here, the term “equivalent circle diameter of a plane” refers to the diameter of a perfect circle having the same area as the plane.

For the deposition of the CAAC-OS film, the following conditions are preferably used.

By increasing the substrate temperature during the deposition, migration of sputtered particles is likely to occur after the sputtered particles reach a substrate surface. Specifically, the substrate temperature during the deposition is higher than or equal to 100° C. and lower than or equal to 740° C., preferably higher than or equal to 200° C. and lower than or equal to 500° C. By increasing the substrate temperature during the deposition, when the flat-plate-like sputtered particles reach the substrate, migration occurs on the substrate surface, so that a flat plane of the sputtered particles is attached to the substrate. At this time, the sputtered particle is charged positively, whereby sputtered particles are attached to the substrate while repelling each other; thus, the sputtered particles do not overlap with each other randomly, and a CAAC-OS film with a uniform thickness can be deposited.

By reducing the amount of impurities entering the CAAC-OS film during the deposition, the crystal state can be prevented from being broken by the impurities. For example, the concentration of impurities (e.g., hydrogen, water, carbon dioxide, or nitrogen) which exist in the deposition chamber may be reduced. Furthermore, the concentration of impurities in a deposition gas may be reduced. Specifically, a deposition gas whose dew point is −80° C. or lower, preferably −100° C. or lower is used.

Furthermore, it is preferable that the proportion of oxygen in the deposition gas be increased and the power be optimized in order to reduce plasma damage at the deposition. The proportion of oxygen in the deposition gas is higher than or equal to 30 vol %, preferably 100 vol %.

Alternatively, the CAAC-OS film is formed by the following method.

First, a first oxide semiconductor layer is formed to a thickness of greater than or equal to 1 nm and less than 10 nm. The first oxide semiconductor layer is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Then, heat treatment is performed to increase the crystallinity of the first oxide semiconductor layer to give the first CAAC-OS film with high crystallinity. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the first oxide semiconductor layer in a short time. At the same time, the heat treatment in an inert atmosphere may generate oxygen vacancies in the first oxide semiconductor layer. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the first oxide semiconductor layer in a shorter time.

The first oxide semiconductor layer with a thickness of greater than or equal to 1 nm and less than 10 nm can be easily crystallized by heat treatment as compared to the case where the first oxide semiconductor layer has a thickness of greater than or equal to 10 nm.

Next, a second oxide semiconductor layer having the same composition as the first oxide semiconductor layer is formed to a thickness of greater than or equal to 10 nm and less than or equal to 50 nm. The second oxide semiconductor layer is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Then, heat treatment is conducted so that the second oxide semiconductor layer is turned into a second CAAC-OS film with high crystallinity by solid phase growth from the first CAAC-OS film. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the second oxide semiconductor layer in a short time. At the same time, the heat treatment in an inert atmosphere may generate oxygen vacancies in the second oxide semiconductor layer. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the second oxide semiconductor layer in a shorter time.

As described above, a CAAC-OS film with a total thickness of greater than or equal to 10 nm can be formed. The CAAC-OS film can be favorably used as the oxide semiconductor layer in the oxide stack.

Next, a method for forming an oxide film in the case where a formation surface has a low temperature (e.g., a temperature lower than 130° C., lower than 100° C., or lower than 70° C., or about a room temperature (higher than or equal to 20° C. and lower than or equal to 25° C.)) because, for example, the substrate is not heated is described.

In the case where the formation surface has a low temperature, sputtered particles fall irregularly to the deposition surface. For example, migration does not occur; therefore, the sputtered particles are randomly deposited on the deposition surface including a region where other sputtered particles have been deposited. That is, an oxide film obtained by the deposition might have a non-uniform thickness and a disordered crystal alignment. The oxide film obtained in the above manner maintains the crystallinity of the sputtered particles to a certain degree and thus has a crystal part (nanocrystal).

For example, in the case where the pressure at the deposition is high, the frequency with which the flying sputtered particle collides with another particle (e.g., an atom, a molecule, an ion, or a radical) of argon or the like is increased. When the flying sputtered particle collides with another particle (resputtered), the crystal structure of the sputtered particle might be broken. For example, when the sputtered particle collides with another particle, the flat-plate-like shape of the sputtered particle cannot be kept, and the sputtered particle might be broken into parts (e.g., atomized). At this time, when atoms obtained from the sputtered particle are deposited on the formation surface, an amorphous oxide semiconductor film might be formed.

In addition, when a process in which a liquid is used or a process in which a solid target is vaporized is employed instead of a sputtering method using a target having a polycrystalline oxide as a starting point, separated atoms fly and are deposited on a deposition surface and thus an amorphous oxide film is formed in some cases. Further, for example, by a laser ablation method, atoms, molecules, ions, radials, clusters, or the like released from the target flies to be deposited over the formation surface; therefore, an amorphous oxide film might be formed.

In each of the resistor and the transistor of one embodiment of the present invention, an oxide semiconductor layer in any of the above crystal states may be used. In the case of including an oxide semiconductor layer with a stacked-layer structure, crystal states of oxide semiconductor layers in the stacked-layer structure may be different from each other. Note that the CAAC-OS film is preferably used as the oxide semiconductor layer serving as the channel of the transistor. The impurity concentration of the oxide semiconductor layer included in the resistor is higher than that of the oxide semiconductor layer included in the transistor, and thus, the crystallinity of the oxide semiconductor layer included in the resistor is lower than that of the oxide semiconductor layer included in the transistor in some cases.

The structures, the methods, and the like described in this embodiment can be combined as appropriate with any of the structures, the methods, and the like described in the other embodiments.

### Embodiment 3

In this embodiment, a semiconductor device of one embodiment of the present invention is described with reference to drawings. Note that in this embodiment, a semiconductor device of one embodiment of the present invention is described taking a display device as an example.

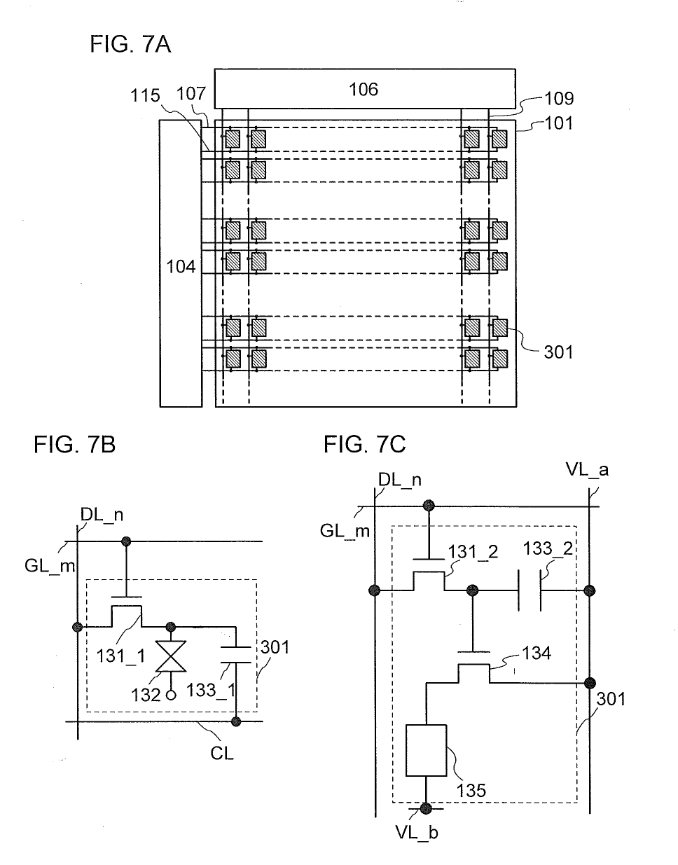

FIG. 7A illustrates an example of a semiconductor device. The semiconductor device in FIG. 7A includes a pixel portion 101, a scan line driver circuit 104, a signal line driver circuit 106, in scan lines 107 which are arranged in parallel or substantially in parallel and whose potentials are controlled by the scan line driver circuit 104, and n signal lines 109 which are arranged in parallel or substantially in parallel and whose potentials are controlled by the signal line driver circuit 106. Further, the pixel portion 101 includes a plurality of pixels 301 arranged in a matrix. Furthermore, capacitor lines 115 arranged in parallel or substantially in parallel are provided along the scan lines 107. Note that the capacitor lines 115 may be arranged in parallel or substantially in parallel along the signal lines 109. The scan line driver circuit 104 and the signal line driver circuit 106 are collectively referred to as a driver circuit portion in some cases.

Each scan line 107 is electrically connected to the n pixels 301 in the corresponding row among the pixels 301 arranged in m rows and n columns in the pixel portion 101. Each signal line 109 is electrically connected to the m pixels 301 in the corresponding column among the pixels 301 arranged in m rows and n columns. Note that in and n are each an integer of 1 or more. Each capacitor line 115 is electrically connected to the n pixels 301 in the corresponding row among the pixels 301 arranged in m rows and n columns Note that in the case where the capacitor lines 115 are arranged in parallel or substantially in parallel along the signal lines 109, each capacitor line 115 is electrically connected to the in pixels 301 in the corresponding column among the pixels 301 arranged in m rows and n columns.

In the semiconductor device described in Embodiment 1, the resistor having the oxide semiconductor layer is included in the driver circuit portion. Further, in the semiconductor device described in Embodiment 1, the transistor having the oxide semiconductor layer may be included in either the driver circuit portion or the pixel portion 101, or in both of them.

In the structure of this embodiment described below, the resistor having the oxide semiconductor layer described in Embodiment 1 is included in at least one of the scan line driver circuit 104 and the signal line driver circuit 106, and the transistor having the oxide semiconductor layer described in Embodiment 1 is included in the pixel 301. That is, the display device described in this embodiment is a display device in which the pixel portion 101 and the driver circuit portion (the scan line driver circuit 104 and the signal line driver circuit 106) are formed over the same substrate.

FIGS. 7B and 7C illustrate circuit configurations that can be used for the pixels 301 in the display device illustrated in FIG. 7A.

The pixel 301 illustrated in FIG. 7B includes a liquid crystal element 132, a transistor 131_1, and a capacitor 133_1. The transistor 131_1 has any of the structures of the transistors described in Embodiment 1.

The potential of one of a pair of electrodes of the liquid crystal element 132 is set according to the specifications of the pixels 301 as appropriate. The alignment state of the liquid crystal element 132 depends on written data. A common potential may be applied to one of the pair of electrodes of the liquid crystal element 132 included in each of the plurality of pixels 301. Further, the potential supplied to one of a pair of electrodes of the liquid crystal element 132 in the pixel 301 in one row may be different from the potential supplied to one of a pair of electrodes of the liquid crystal element 132 in the pixel 301 in another row.

As examples of a driving method of the display device including the liquid crystal element 132, any of the following modes can be given: a TN mode, an STN mode, a VA mode, an ASM (axially symmetric aligned micro-cell) mode, an OCB (optically compensated birefringence) mode, an FLC (ferroelectric liquid crystal) mode, an AFLC (antiferroelectric liquid crystal) mode, an MVA mode, a PVA (patterned vertical alignment) mode, an IPS mode, an FFS mode, a TBA (transverse bend alignment) mode, and the like. Other examples of the driving method of the display device include ECB (electrically controlled birefringence) mode, PDLC (polymer dispersed liquid crystal) mode, PNLC (polymer network liquid crystal) mode, and a guest-host mode. Note that the present invention is not limited to these examples, and various liquid crystal elements and driving methods can be applied to the liquid crystal element and the driving method thereof.

The liquid crystal element may be formed using a liquid crystal composition including liquid crystal exhibiting a blue phase and a chiral material. The liquid crystal exhibiting a blue phase has a short response time of 1 msec or less and is optically isotropic; therefore, alignment treatment is not necessary and viewing angle dependence is small.

In the pixel 301 in the in-th row and the n-th column, one of a source electrode and a drain electrode of the transistor 131_1 is electrically connected to a signal line DL_n, and the other is electrically connected to the other of a pair of electrodes of the liquid crystal element 132. A gate electrode of the transistor 131_1 is electrically connected to a scan line GL_m. The transistor 131_1 has a function of controlling whether to write a data signal by being turned on or off.

One of a pair of electrodes of the capacitor 133_1 is electrically connected to a wiring to which a potential is supplied (hereinafter referred to as a capacitor line CL), and the other is electrically connected to the other of the pair of electrodes of the liquid crystal element 132. The potential of the capacitor line CL is set in accordance with the specifications of the pixel 301 as appropriate. The capacitor 133_1 functions as a storage capacitor for storing written data.

For example, in the display device including the pixel 301 in FIG. 7B, the pixels 301 are sequentially selected row by row by the scan line driver circuit 104, whereby the transistors 131_1 are turned on and a data signal is written.

When the transistors 131_1 are turned off, the pixels 301 in which the data has been written are brought into a holding state. This operation is sequentially performed row by row; thus, an image is displayed.

The pixel 301 illustrated in FIG. 7C includes a transistor 131_2, a capacitor 133_2, a transistor 134, and a light-emitting element 135. Any of the structures of the transistors described in Embodiment 1 is used for at least one of the transistor 1312 and the transistor 134.

One of a source electrode and a drain electrode of the transistor 1312 is electrically connected to a wiring to which a data signal is supplied (hereinafter referred to as signal line DL_n). A gate electrode of the transistor 131_2 is electrically connected to a wiring to which a gate signal is supplied (hereinafter referred to as scan line GL_m).

The transistor 131_2 has a function of controlling whether to write a data signal by being turned on or off.

One of a pair of electrodes of the capacitor 133_2 is electrically connected to a wiring to which a potential is supplied (hereinafter referred to as a potential supply line VL_a), and the other is electrically connected to the other of the source electrode and the drain electrode of the transistor 131_2.

The capacitor 133_2 functions as a storage capacitor for storing written data.

One of a source electrode and a drain electrode of the transistor 134 is electrically connected to the potential supply line VL_a. Further, a gate electrode of the transistor 134 is electrically connected to the other of the source electrode and the drain electrode of the transistor 131_2.

One of an anode and a cathode of the light-emitting element 135 is electrically connected to a potential supply line VL_b, and the other is electrically connected to the other of the source electrode and the drain electrode of the transistor 134.

As the light-emitting element 135, an organic electroluminescent element (also referred to as an organic EL element) or the like can be used, for example. Note that the light-emitting element 135 is not limited to organic EL elements; an inorganic EL element including an inorganic material can be used.

A high power supply potential VDD is supplied to one of the potential supply line VL_a and the potential supply line VL_b, and a low power supply potential VSS is supplied to the other.

In the display device including the pixel 301 in FIG. 7C, the pixels 301 are sequentially selected row by row by the scan line driver circuit 104, whereby the transistors 131_2 are turned on and a data signal is written.

When the transistors 131_2 are turned off, the pixels 301 in which the data has been written are brought into a holding state. Further, the amount of current flowing between the source electrode and the drain electrode of the transistor 134 is controlled in accordance with the potential of the written data signal. The light-emitting element 135 emits light with a luminance corresponding to the amount of flowing current. This operation is sequentially performed row by row; thus, an image is displayed.

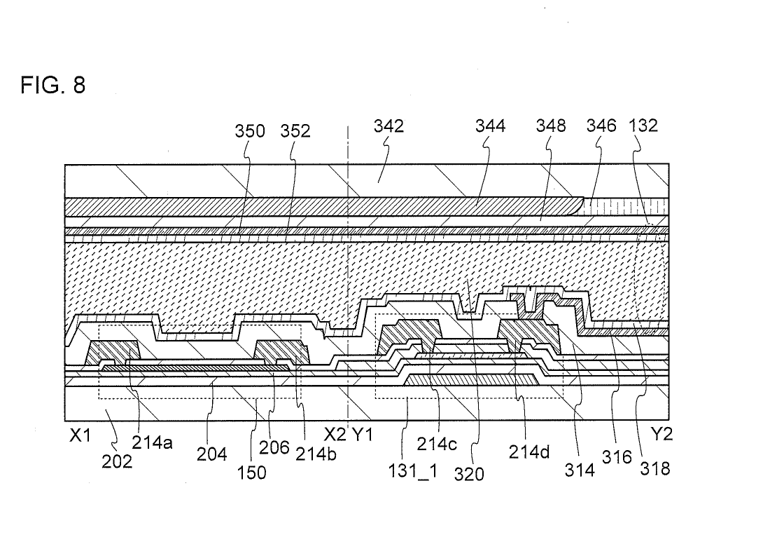

FIG. 8 is a cross-sectional view showing a specific example of a structure of a display device including the pixel 301 shown in FIG. 7B and the resistor included in the driver circuit portion. A cross section X1-X2 in FIG. 8 is a cross-sectional view of the resistor 150 included in the driver circuit portion (including the scan line driver circuit 104 and the signal line driver circuit 106). A cross section Y1-Y2 is a cross-sectional view of the transistor 131_1 and the liquid crystal element 132 that are included in the pixel 301. In this embodiment, a liquid crystal display device of a vertical electric field mode is described.

In the liquid crystal display device described in this embodiment, a liquid crystal element 132 is provided between a pair of substrates (a substrate 202 and a substrate 342).

The liquid crystal element 132 includes the light-transmitting conductive film 316 over the substrate 202, films controlling alignment (hereinafter referred to as alignment films 318 and 352), a liquid crystal layer 320, and a conductive film 350. Note that the light-transmitting conductive film 316 functions as one electrode of the liquid crystal element 132, and the conductive film 350 functions as the other electrode of the liquid crystal element 132.

Thus, a “liquid crystal display device” refers to a device including a liquid crystal element. Note that the liquid crystal display device includes a driver circuit for driving a plurality of pixels and the like. The liquid crystal display device may also be referred to as a liquid crystal module including a control circuit, a power supply circuit, a signal generation circuit, a backlight module, and the like provided over another substrate.

The structure of the resistor 150 included in the driver circuit portion can be the same as that described in Embodiment 1. The structure of the transistor 131_1 included in the pixel portion can be the same as that of the transistor 100 described in Embodiment 1. Note that this embodiment is not limited thereto. Other structural examples of the resistor and the transistor described in Embodiment 1 may be used for the display device.

An insulating layer 314 is provided over the electrode layers 214a to 214d. The conductive film 316 having a light-transmitting property and serving as a pixel electrode is connected to the electrode layer 214d in an opening portion provided in the insulating layer 314.

The insulating layer 314 can be formed using an inorganic insulating material or an organic insulating material as a single layer or a stack of layers. Note that a structure in which the insulating layer 314 is not provided may be employed. When the structure without the insulating layer 314 is employed, it is possible to omit a mask that is used to form the opening portion for connecting the light-transmitting conductive film 316 to the electrode layer 214d.

For the light-transmitting conductive film, a light-transmitting conductive material such as indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added can be used.

A film having a colored property (hereinafter referred to as a colored film 346) is formed on the substrate 342. The colored film 346 functions as a color filter. Further, a light-blocking film 344 adjacent to the colored film 346 is formed on the substrate 342. The light-blocking film 344 functions as a black matrix. The colored film 346 is not necessarily provided in the case where the display device is a monochrome display device, for example.

The colored film 346 is a colored film that transmits light in a specific wavelength range. For example, a red (R) color filter for transmitting light in a red wavelength range, a green (G) color filter for transmitting light in a green wavelength range, a blue (B) color filter for transmitting light in a blue wavelength range, or the like can be used.

The light-blocking film 344 preferably has a function of blocking light in a particular wavelength region, and can be a metal film or an organic insulating film including a black pigment.

An insulating layer 348 is formed on the colored film 346. The insulating layer 348 functions as a planarization layer or suppresses diffusion of impurities in the colored film 346 to the liquid crystal element side.

The conductive film 350 is formed on the insulating layer 348. The conductive film 350 functions as the other of the pair of electrodes of the liquid crystal element 132 in the pixel portion. Note that an insulating film that functions as an alignment film may be additionally formed on the light-transmitting conductive film 316 and the conductive film 350.

The liquid crystal layer 320 is formed between the light-transmitting conductive film 316 and the conductive film 350. The liquid crystal layer 320 is sealed between the substrate 202 and the substrate 342 with the use of a sealant (not illustrated). The sealant is preferably in contact with an inorganic material to prevent entry of moisture and the like from the outside.

A spacer may be provided between the light-transmitting conductive film 316 and the conductive film 350 to maintain the thickness of the liquid crystal layer 320 (also referred to as a cell gap).

As described above, in the display device in this embodiment, transistors included in the driver circuit portion and/or the pixel portion and the resistor included in the driver circuit portion can be formed over the same substrate at the same time. Thus, the resistor can be fainted without increasing the manufacturing cost and the like.

The structures, the methods, and the like described in this embodiment can be combined as appropriate with any of the structures, the methods, and the like described in the other embodiments.

### Embodiment 4

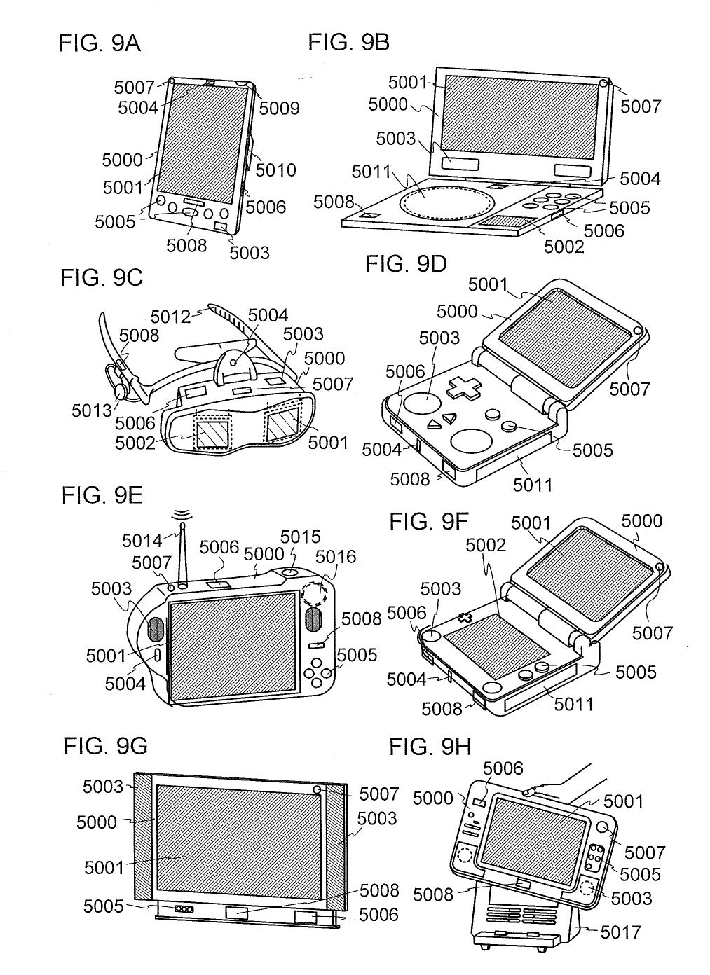

In this embodiment, examples of an electronic device in which the semiconductor device which is one embodiment of the present invention is included in a display portion will be described with reference to FIGS. 9A to 9H.

FIGS. 9A to 9H illustrate electronic appliances. These electronic devices can include a housing 5000, a display portion 5001, a speaker 5003, an LED lamp 5004, operation keys 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 9A illustrates a mobile computer, which can include a switch 5009, an infrared port 5010, and the like in addition to the above components. FIG. 9B illustrates a portable image regenerating device provided with a memory medium (e.g., a DVD regenerating device), which can include a second display portion 5002, a memory medium reading portion 5011, and the like in addition to the above objects. FIG. 9C illustrates a goggle-type display, which can include the second display portion 5002, a support 5012, an earphone 5013, and the like in addition to the above components. FIG. 9D illustrates a portable game machine, which can include the memory medium reading portion 5011 and the like in addition to the above components. FIG. 9E illustrates a digital camera with a television receiver function which can include an antenna 5014, a shutter button 5015, an image receiving portion 5016, and the like in addition to the above objects. FIG. 9F shows a portable game console, which can include the second display portion 5002, the memory medium reading portion 5011, and the like in addition to the above objects. FIG. 109G illustrates a television set, which can include a tuner, an image processing portion, and the like in addition to the above components. FIG. 9H illustrates a portable television receiver, which can include a charger 5017 capable of transmitting and receiving signals and the like in addition to the above objects.

The electronic devices illustrated in FIGS. 9A to 9H can have a variety of functions, for example, a function of displaying a variety of information (e.g., a still image, a moving image, and a text image) on a display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading program or data stored in a recording medium and displaying the program or data on a display portion. Further, the electronic device including a plurality of display portions can have a function of displaying image information mainly on one display portion while displaying text information on another display portion, a function of displaying a three-dimensional image by displaying images where parallax is considered on a plurality of display portions, or the like. Furthermore, the electronic device including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that functions which can be provided for the electronic devices illustrated in FIGS. 9A to 9H are not limited to those described above, and the electronic devices can have a variety of functions.

The electronic devices described in this embodiment have a feature that they have the semiconductor device of the present invention in a display portion for displaying some sort of information.

The structures, the methods, and the like described in this embodiment can be combined as appropriate with any of the structures, the methods, and the like described in the other embodiments.

This application is based on Japanese Patent Application serial No. 2013-077615 filed with Japan Patent Office on Apr. 3, 2013, the entire contents of which are hereby incorporated by reference.

What is claimed is:

1. A semiconductor device comprising:
a resistor and a transistor over a substrate,
wherein the resistor comprises:
a first oxide semiconductor layer;
a nitride insulating layer covering the first oxide semiconductor layer; and
a first electrode and a second electrode electrically connected to the first oxide semiconductor layer in contact holes provided in the nitride insulating layer,
wherein the transistor comprises:
a gate electrode layer;
a second oxide semiconductor layer overlapping the gate electrode layer;
an insulating layer between the gate electrode layer and the second oxide semiconductor layer;
an oxide insulating layer covering the second oxide semiconductor layer; and
a third electrode and a fourth electrode electrically connected to the second oxide semiconductor layer in contact holes provided in the oxide insulating layer, and
wherein a carrier density of the first oxide semiconductor layer is higher than a carrier density of the second oxide semiconductor layer.

2. The semiconductor device according to claim 1,
wherein a length of a path through which a carrier flows in the resistor is longer than a length of a path through which a carrier flows in the transistor.

3. The semiconductor device according to claim 1,
wherein the transistor is included in a pixel portion, and
wherein the resistor is included in a driver circuit portion.

4. The semiconductor device according to claim 1, wherein the first oxide semiconductor layer has a same composition as the second oxide semiconductor layer.

5. The semiconductor device according to claim 1, wherein the semiconductor device is one selected from the group consisting of a mobile computer, a portable image regenerating device, a goggle-type display, a portable game machine, a digital camera, and a television set.

6. A semiconductor device comprising:
a resistor and a transistor over a substrate,
wherein the resistor comprises:
a first nitride insulating layer;
a first oxide semiconductor layer over the first nitride insulating layer;
a second nitride insulating layer covering the first oxide semiconductor layer; and
a first electrode and a second electrode electrically connected to the first oxide semiconductor layer in contact holes provided in the second nitride insulating layer,
wherein the transistor comprises:
a gate electrode layer;
the first nitride insulating layer over the gate electrode layer;
a first oxide insulating layer over the first nitride insulating layer;
a second oxide semiconductor layer overlapping the gate electrode layer with the first nitride insulating layer and the first oxide insulating layer interposed therebetween;
a second oxide insulating layer covering the second oxide semiconductor layer;
the second nitride insulating layer over the second oxide insulating layer; and
a third electrode and a fourth electrode electrically connected to the second oxide semiconductor layer in contact holes provided in the second nitride insulating layer and the second oxide insulating layer, and
wherein a carrier density of the first oxide semiconductor layer is higher than a carrier density of the second oxide semiconductor layer.

7. The semiconductor device according to claim 6,
wherein the resistor includes the first oxide insulating layer between the first nitride insulating layer and the first oxide semiconductor layer.

8. The semiconductor device according to claim 6,
wherein a length of a path through which a carrier flows in the resistor is longer than a length of a path through which a carrier flows in the transistor.

9. The semiconductor device according to claim 6,
wherein the transistor is included in a pixel portion, and
wherein the resistor is included in a driver circuit portion.

10. The semiconductor device according to claim 6, wherein the first oxide semiconductor layer has a same composition as the second oxide semiconductor layer.

11. The semiconductor device according to claim 6, wherein the semiconductor device is one selected from the group consisting of a mobile computer, a portable image regenerating device, a goggle-type display, a portable game machine, a digital camera, and a television set.
